(19) United States
(12) Patent Application Publication
(10) Pub. No.: US 2023/0156482 A1
(43) Pub. Date: May 18, 2023

(54) SYSTEMS AND METHODS FOR FEATURE IMPORTANCE DETERMINATION IN A WIRELESS NETWORK MODELING AND SIMULATION SYSTEM

(71) Applicant: Verizon Patent and Licensing Inc., Basking Ridge, NJ (US)

(72) Inventors: Farid Khafizov, Plano, TX (US); Mark Ernest Newbury, Hillsborough, NJ (US)

(73) Assignee: Verizon Patent and Licensing Inc., Basking Ridge, NJ (US)

(21) Appl. No.: 17/525,418

(22) Filed: Nov. 12, 2021

(51) Int. Cl. H04W 16/18; G06F 30/20; H04W 16/22

(52) U.S. Cl. CPC H04W 16/18; G06F 30/20; H04W 16/22

(57) ABSTRACT

A system described herein may identify a relative feature importance of a set of features in a modeling and/or simulation system. The same set of features may be provided to a group of different models. A relative feature importance of each feature of the set of features may be determined, on a per-model basis, based on comparing outputs of the model with and without particular features of the set of features. A relative feature of each feature may be further be determined on an inter-model basis by identifying features that are commonly ranked highly in the per-model rankings. An iterative process may evaluate the highest ranked, next-highest ranked, etc. features across multiple models. A simulation system may utilize the rankings to more efficiently perform one or more simulations, which may include omitting one or more features of the set of features when performing the simulations.

### BACKGROUND

Wireless networks may utilize simulations in order to test network systems, such as base stations, User Equipment (“UEs”), network functions, and/or other devices or systems of the wireless networks. The simulations may include modifying parameters of devices or systems of the wireless networks, measuring or otherwise identifying the results of modifying such parameters (e.g., identifying Key Performance Indicators (“KPIs”), performance metrics, etc.), and/or other suitable operations. The quantity of configuration parameters, KPIs, performance metrics, etc. may be relatively large.

### BRIEF DESCRIPTION OF THE DRAWINGS

FIG. 1 illustrates an example overview of one or more embodiments described herein;

FIGS. 2 and 3 illustrate examples of inputs and outputs of one or more models, in accordance with some embodiments;

FIG. 4 illustrates an example determination of feature importance of a given set of features with respect to a particular model;

FIGS. 5-11 illustrate an example determination of feature importance of a given set of features with respect to multiple models;

FIG. 12 illustrates an example overview of one or more embodiments described herein;

FIG. 13 illustrates an example process for determining feature importance of a given set of features, in accordance with some embodiments;

FIG. 14 illustrates an example environment in which one or more embodiments, described herein, may be implemented;

FIG. 15 illustrates an example arrangement of a radio access network (“RAN”), in accordance with some embodiments;

FIG. 16 illustrates an example arrangement of an Open RAN (“O-RAN”) environment in which one or more embodiments, described herein, may be implemented; and

FIG. 17 illustrates example components of one or more devices, in accordance with one or more embodiments described herein.

### DETAILED DESCRIPTION OF EXAMPLE EMBODIMENTS

The following detailed description refers to the accompanying drawings. The same reference numbers in different drawings may identify the same or similar elements.

In a simulation system for a wireless network, the quantity of configuration parameters, KPIs, performance metrics, etc. may be relatively large. As such, identifying configuration parameters, KPIs, performance metrics, etc. that have a material effect on the results of a given simulation may be relatively time- and/or processor-intensive. Further, implementing or attempting to model all configuration parameters, KPIs, metrics, etc. may be relatively difficult, and/or may increase the complexity of simulations that utilize or are based on such configuration parameters, KPIs, metrics, etc.

Embodiments described herein may allow for a determination of features (e.g., configuration parameters, KPIs, performance metrics, etc.) that are relevant or significant for one or more network simulation models, and the use of such determined features in executing one or more simulations. The identification of such features may allow for the paring down or reducing of the quantity of features to be implemented in the one or more simulations, which may reduce the complexity of such simulations. Further, models (e.g., network simulation models, predictive models, and/or other types of models) may model dependencies, correlations, etc. between different features.

Paring down or reducing the quantity of features may facilitate the more efficient or faster identification of features that are correlated, dependent upon each other, or are otherwise related. For example, when identifying features that are correlated, a system described herein may evaluate, or prioritize the evaluation of, features that have been identified as more relevant, more significant, etc. for measures of correlation, dependency, etc., and may omit or de-prioritize features that have been identified as less relevant, less significant, etc. As additionally described below, the identification of features that are correlated or otherwise related may aid in the testing or validation of models that were generated, modified, trained, etc. based on the pared set of features in accordance with some embodiments. In this manner, a measure of accuracy, predictiveness, etc. of such models may be efficiently determined.

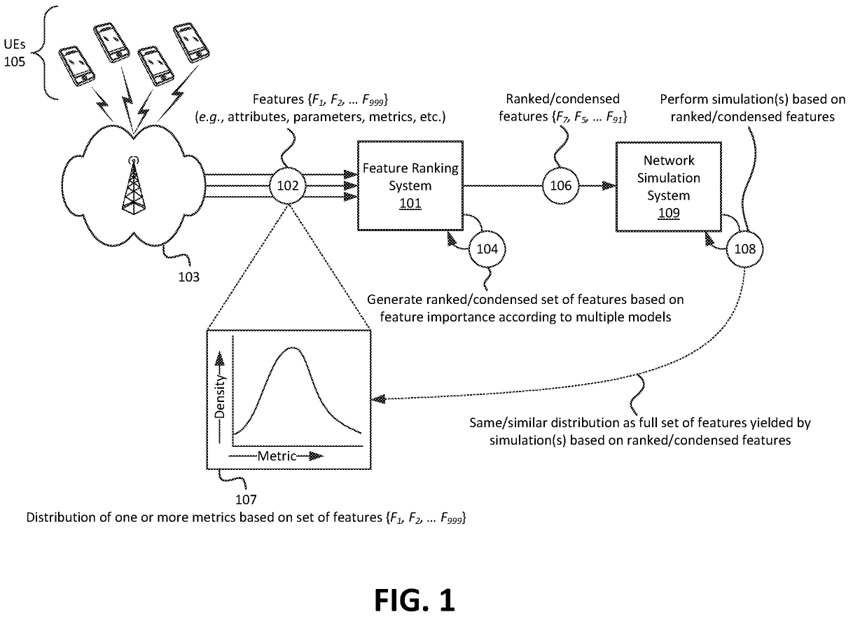

As shown in FIG. 1, for example, Feature Ranking System (“FRS”) 101 may receive (at 102) information regarding a given wireless network 103 and/or UEs 105 that are communicatively coupled to wireless network 103. Such information may include configuration parameters of wireless network 103 and/or UEs 105, attributes of wireless network 103 and/or UEs 105, attributes of a physical environment associated with wireless network 103 and/or UEs 105, metrics and/or KPIs associated with wireless network 103 and/or UEs 105, and/or other suitable information. Generally, the information received (at 102) by FRS 101 may include any measurable or identifiable configuration parameter, attribute, KPI, metric, etc. associated with wireless network 103 and/or UEs 105.

Such information may be received from wireless network 103, from UEs 105, and/or some other device or system that measures, identifies, and/or provides such information to FRS 101 (e.g., via an application programming interface (“API”) or some other suitable communication pathway). In some embodiments, wireless network 103 and UEs 105 may include one or more real-world networks, devices, systems, etc. In some embodiments, wireless network 103 and UEs 105 may be simulated by one or more simulation systems, which generate and provide KPIs, metrics, etc. based on configuration parameters.

The configuration parameters and/or attributes associated with wireless network 103 may include RAN or base station configuration parameters, such as beamforming parameters (e.g., azimuth angle, beam width, antenna power, etc.), Multiple-Input Multiple-Output (“MIMO”) parameters, Physical Resource Block (“PRB”) allocation parameters, traffic queueing parameters, access control parameters, handover thresholds, or other suitable RAN or base station configuration parameters. In some embodiments, the configuration parameters may include routing parameters, neighbor cell lists (“NCLs”), handover thresholds, routing parameters (e.g., routing tables, Domain Name System (“DNS”) tables, etc.), containerized virtual environment configuration parameters, power saving parameters, or any other suitable parameters of wireless network 103 that may be configured, adjusted, etc. In some embodiments, the attributes and/or parameters associated with wireless network 103 may include location-based features, such as a geographical location associated with one or more elements of wireless network 103, geographical regions associated with one or more coverage areas of wireless network 103, particulate matter density associated with one or more geographical regions associated with wireless network 103, topographical features associated with one or more geographical regions associated with wireless network 103, a quantity of UEs 105 connected to a particular portion of wireless network 103 (e.g., connected to a particular RAN and/or base station), etc.

The configuration parameters and/or attributes associated with UEs 105 may include device types of UEs 105 (e.g., mobile phone, tablet, Internet of Things (“IoT”) device, Machine-to-Machine (“M2M”) device, etc.), makes and/or models of UEs 105, identifiers of UEs 105 (e.g., International Mobile Subscriber Identity (“IMSI”) values, Subscription Permanent Identifier (“SUPI”) values, etc.), Quality of Service (“QoS”) and/or Service Level Agreement (“SLA”) information associated with UEs 105, and/or other parameters and/or attributes associated with UEs 105. While example parameters are discussed above, in practice, the configuration parameters and/or attributes associated with wireless network 103 and/or UEs 105 may include one or more other suitable parameters or attributes.

The KPIs, metrics, etc. associated with wireless network 103 and/or UEs 105 may include measurable or identifiable information associated with the operation and/or simulation of wireless network 103 and/or UEs 105. Such KPIs and/or metrics may include information such as latency between one or more network devices and/or between wireless network 103 and one or more UEs 105, uplink and/or downlink throughput associated with one or more UEs 105, uplink and/or downlink throughput associated with one or more portions of wireless network 103, channel quality of radio frequency (“RF”) communications between one or more UEs 105 and one or more elements of wireless network 103, quantity or proportion of dropped calls associated with wireless network 103, and/or other suitable KPIs and/or metrics. While example KPIs and/or metrics are discussed above, in practice, the KPIs and/or metrics associated with wireless network 103 and/or UEs 105 may include one or more other suitable KPIs and/or metrics.

As described herein, a given configuration parameter, attribute, metric, KPI, etc. (and/or a combination thereof) may be a feature of one or more models that may be used in modeling and/or simulation, such as the simulation of operation of wireless network 103 and/or UE 105. As such, the quantity of features (referred herein to as features F) may be relatively large (e.g., 999 features F₁ through F₉₉₉, in the example shown here). One or more of the features may be associated with a particular distribution as a function of the set of features. For example, graph 107 represents the incidence of occurrence (e.g., shown in FIG. 1 as “density”) of particular values for a particular metric, KPI, classification, category, etc. when the set of features {F₁, F₂, ... F₉₉₉} is associated with wireless network 103 and/or UEs 105. For example, the particular metric, KPI, classification, category, etc. may include a particular performance metric (e.g., latency, throughput, etc.), a configuration parameter (e.g., beamforming configuration, MIMO configuration, etc.), a location-based attribute (e.g., geographical location, incidence of a particular topographical features, etc.), and/or other suitable attributes or metrics. In some embodiments, multiple instances of graph 107 may represent the distribution of one or more other features as a function of the full set of features {F₁, F₂, ... F₉₉₉}. In some embodiments, another instance of graph 107 may include the distribution of one or more derived values that is based on one or more features, such as one or more scores, composite values, etc.

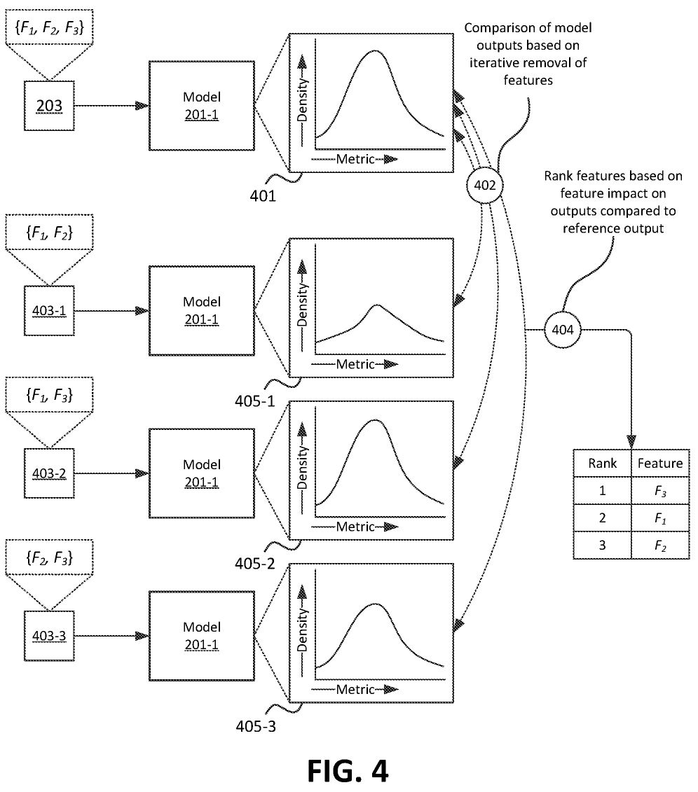

As further shown, FRS 101 may generate (at 104) a ranked and/or condensed set of features based on feature importance of some or all of the features of the full set of features {F₁, F₂, ... F₉₉₉}, in accordance with embodiments described in greater detail below. For example, as discussed below (e.g., with respect to FIG. 4), FRS 101 may determine intra-model and/or inter-model feature importance of some or all of the features of the set of features {F₁, F₂, ... F₉₉₉} by evaluating outputs of one or models under different conditions. Briefly, for example, FRS 101 may provide, in a first iteration, a set of configuration parameters indicated by the set of features (e.g., some or all features of the full set of features {F₁, F₂, ... F₉₉₉}) to a particular model to generate a first set of outputs, which may include KPIs, metrics, etc. FRS 101 may further provide, in second or subsequent iterations, altered sets of features to the same model. For example, in a second iteration, the altered set of features include a subset (e.g., fewer than all) of the set of features provided to the model in the first iteration, to generate a second set of outputs. FRS 101 may compare the outputs of the second and subsequent iterations of the model to the outputs of the first iteration of the model, and may identify the importance or impact of particular features based on an impact that removing such features had on the outputs of the second and subsequent iterations of the model, as compared to the outputs of the first iteration. FRS 101 may, in some embodiments, rank such features based on the impact that each feature had on the outputs of the model, where features with greater impact on the outputs of the model may be more important than features with lesser (or no) impact on the outputs of the model.

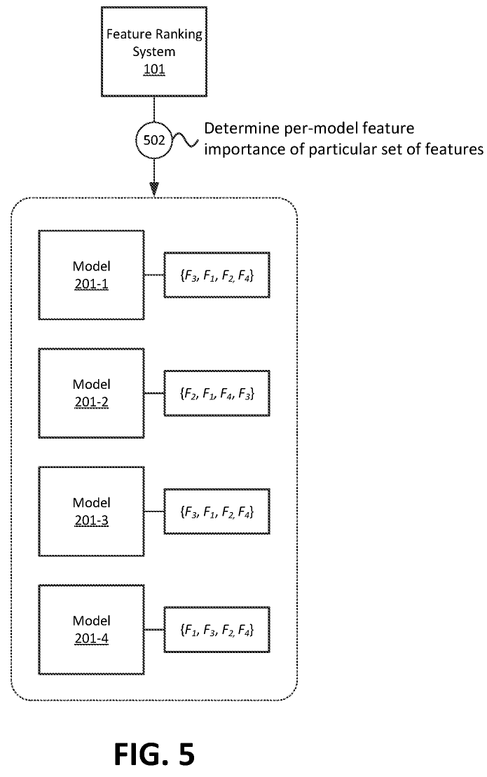

FRS 101 may perform a similar procedure with multiple models, such that FRS 101 determines a per-model ranking of features based on their importance with respect to each respective model. As also discussed in greater detail below (e.g., with respect to FIGS. 5-11), FRS 101 may identify an inter-model feature importance by identifying features that are commonly ranked highly for each model. FRS 101 may further rank some or all of the features of the set of features {F₁, F₂, ... F₉₉₉} based on the inter-model feature importance. In some embodiments, FRS 101 may condense the features of the full set of features {F₁, F₂, ... F₉₉₉}, by eliminating (e.g., not including) features that are below a particular rank, features that are associated with a score or measure of importance that is below a threshold, etc.

FRS 101 may further provide (at 106) the ranked and/or condensed set of features (shown in FIG. 1 as “{F₇, F₅, ... F₉₁}”) to Network Simulation System (“NWS”) 109. In some embodiments, the ranked and/or condensed set of features may include only configuration parameters. In some embodiments, FRS 101 may provide configuration parameters to NSS 109 that are based on some or all of the ranked and/or condensed set of features. In some embodiments, FRS 101 may determine which features of the ranked and/or condensed set of features include configuration parameters. In some embodiments, the ranked and/or condensed set of features may include features that are based on some or all of the KPIs, metrics, etc. associated with wireless network 103 and/or UEs 105.

NSS 109 may perform (at 108) one or more simulations (e.g., simulations of wireless network 103 with UEs 105, and/or of one or more other networks and/or sets of UEs) based on the received ranked and/or condensed set of features. As noted above, the ranked and/or condensed set of features may include fewer configuration parameters than the full set of features. For example, configuration parameters for wireless network 103 and/or UEs 105 that are associated with lower ranked (e.g., less important, less significant, etc.) features may not be implemented by NSS 109 during the simulation, thereby reducing the complexity of the simulation performed by NSS 109. Since the remaining features in the ranked and/or condensed set of features may be features identified as having the highest degree of relevance or importance, the resulting distribution of KPIs or metrics (e.g., including one or more KPIs or metrics associated with feature F₁) may be the same or similar to the distribution associated with the full set of features {F₁, F₂, ... F₉₉₉}. Further, the identified set of features may be used in a testing or simulation environment to identify KPIs, metrics, etc. that may result from modifying some of the features identified as relatively important or relevant, thereby enhancing the predictivity or reliability of simulations performed by NSS 109.

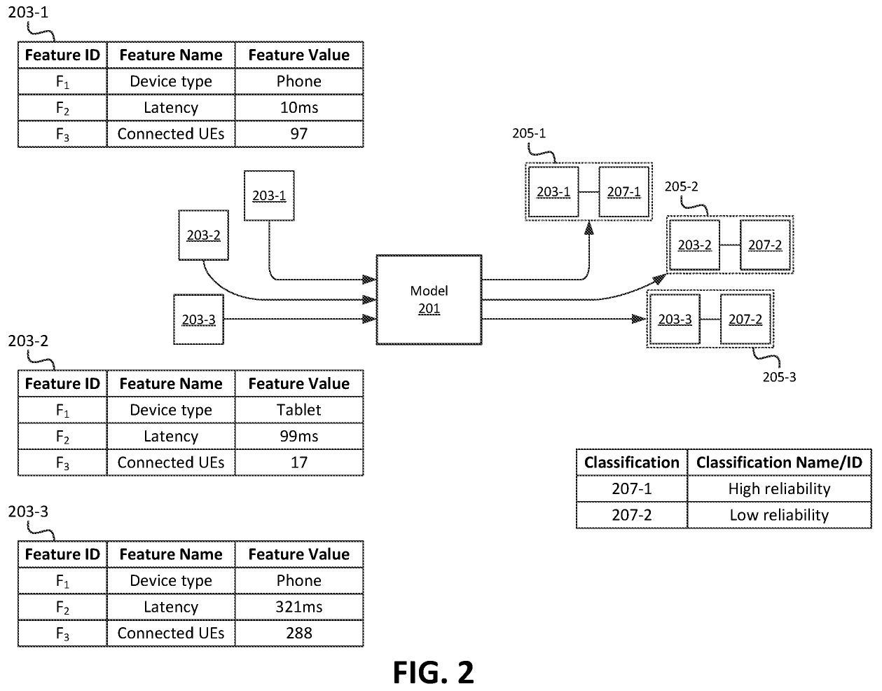

As noted above, in the generation (at 104) of a ranked and/or condensed set of features, FRS 101 may utilize multiple models. An example of one such model 201 is shown in FIG. 2. In this example, model 201 may take a set of inputs 203 (e.g., where the set of inputs in this example include three example features {F₁, F₂, F₃}) as inputs, and may generate a set of outputs 205 based on the set of features. One particular set of outputs 205 may, for example, associate the set of inputs 203 with a particular classification 207.

In the example here, model 201 may generate a set of outputs 205-1 that associates a first set of inputs 203-1 with a first classification 207-1, may generate a second set of outputs 205-2 that associates a second set of inputs 203-2 with a second classification 207-2, and may generate a third set of outputs 205-3 that associates a third set of inputs 203-3 and the second classification 207-2 (e.g., inputs 203-2 and 203-3 may be associated with the same classification 207-2). The set of inputs 203 may include, for example, features associated with a device type attribute (feature F₁), a latency metric (feature F₂), and a quantity of connected UEs attribute (F₃). Model 201 may include any suitable modeling, computations, artificial intelligence/machine learning (“AI/ML”) techniques, etc. to determine particular classifications 207 for each set of inputs 203 (e.g., each instance of the set of features {F₁, F₂, F₃}). For example, model 201 may determine that the set of inputs 203-1 are associated with a “high reliability” classification, and that the sets of inputs 203-2 and 203-2 are associated with a “low reliability” classification. In some embodiments, in addition to or in lieu of classifications (e.g., classifications 207), model 201 may generate one or more other suitable types of outputs, such as scores, values, etc. Further, in some embodiments, additional and/or different classifications may be determined with respect to respective sets of inputs 203. In some embodiments, model 201 may include one or more multi-dimensional models that associate a given set of inputs 203 with multiple classifications 207.

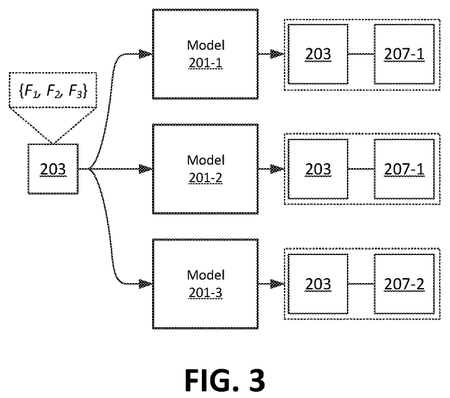

In some embodiments, as shown in FIG. 3, FRS 101 may utilize (e.g., at 104) multiple different models 201 to perform computations, generate outputs (e.g., classifications 207, scores, and/or other outputs), and/or perform other suitable operations based on a particular set of inputs 203. For example, models 201-1, 201-2, and 201-3 may receive the same set of inputs 203 (e.g., including the set of features {F₁, F₂, F₃}) as inputs, and may generate classifications 207 based on different computations, modeling, and/or other operations respectively performed based on models 201-1, 201-2, and 201-3. For example, model 201-1 may provide a particular classification 207-1 based on performing operations on the set of inputs 203, model 201-2 may provide the same particular classification 207-1 based on performing operations (e.g., different operations from those performed by model 201-1) on the same set of inputs 203, and model 201-3 may provide a different classification 207-2 based on performing operations on the same set of inputs 203.

FRS 101 may, for one or more models 201, identify (at 104) a measure of importance of one or more features. For example, as shown in FIG. 4, FRS 101 may compare (at 402) the outputs of a particular model 201-1 based on providing multiple modified sets of features to model 201-1 and comparing outputs provided by model 201-1 based on the modified sets of features. In this example, FRS 101 may generate a set of outputs 205 based on a set of inputs 203 that include features {F₁, F₂, F₃}. The set of outputs based on providing features {F₁, F₂, F₃} may be represented as distribution 401. As similarly discussed above, distribution 401 may indicate an incidence of occurrence (e.g., density) of particular values for one or more metrics, KPIs, classifications, categories, etc. In some embodiments, outputs 205 generated based on model 201-1 may be represented by and/or may include other types of representations or formats than distribution 401. For example, as discussed above, outputs 205 may include one or more scores, classifications, etc. In some embodiments, distribution 401 may represent an intermediate computation performed by model 201-1 in order to ultimately generate a particular set of outputs 205 based on the set of inputs 203. In this sense, distribution 401 may be a “reference” or “control” set of outputs with respect to the operations described below.

FRS 101 may further utilize the same model 201-1 with modified inputs 403-1 to generate a respective set of outputs, represented in FIG. 4 by distribution 405-1. Modified inputs 403-1 may include a subset of the features of inputs 203. For example, while the set of inputs 203 includes features {F₁, F₂, F₃}, the modified set of inputs 403-1 may include features {F₁, F₂}. In other words, the modified set of inputs 403-1 may omit one or more features (feature F₃, in this example) as compared to the set of inputs 203. Based on the omission of the one or more features, the outputs associated with the modified set of inputs 403-1 may be different from the outputs associated with the set of inputs 203. For example, distribution 405-1 may be different from distribution 401.

FRS 101 may similarly utilize the same model 201-1 with other sets of modified inputs 403-2 and 403-3 to generate or identify distributions 405-2 and 405-3, respectively. In some embodiments, FRS 101 may iteratively perform similar operations with differently modified sets of inputs, such as sets of features with multiple features or combinations of features omitted, compared to the features of the set of inputs 203.

As noted above, FRS 101 may compare (at 402) the respective outputs of model 201-1 based on the modified sets of inputs 403 to the “reference” output of model 201-1 (e.g., based on the initial set of inputs 203) to identify respective measures of similarity, correlation, difference, etc. (referred to herein simply as “measures of similarity” for the sake of brevity). For example, FRS 101 may use one or more data analysis techniques, image recognition techniques, or other suitable techniques to identify a measure of similarity between each distribution 405 to reference distribution 401.

FRS 101 may rank (at 404) the features associated with the set of inputs 203 based on the impact that the removal of respective features had on the output generated based on model 201-1. The “impact” of removal of a given feature may be based on the difference between the output of model 201-1 with that feature removed (e.g., as represented by distributions 405), as compared to the output of model 201-1 with the full set of features, and/or without that feature removed (e.g., as represented by reference distribution 401).

For example, out of the set of distributions 405-1 through 405-3, distribution 405-1 may be the most dissimilar, and/or may have the lowest measure of similarity, to reference distribution 401. As such, the feature(s) omitted in the modified set of inputs 403-1 (i.e., F₃ in this example) may be identified as the most important feature out of the set of features {F₁, F₂, F₃}. Further in this example, distribution 405-3 (e.g., where F₁ is omitted from inputs 403-3) may be relatively more similar to distribution 401 than distribution 405-1, and distribution 405-2 (e.g., where F₂ is omitted from inputs 403-2) may be relatively more similar to distribution 401 than distributions 405-1 and 405-3. Thus, feature F₁ may be identified as the second-most important feature, and feature F₂ may be identified as the third-most important (e.g., least important) feature of the set of features {F₁, F₂, F₃}. Generally, for example, if the removal of a given feature has less impact on the output of a given model 201, then that feature may be less important than a feature whose omission has a relatively greater impact on the output of the given model 201.

In some embodiments, FRS 101 may provide the same set of inputs 203 (e.g., including a particular set of features) to multiple models and may, in a similar manner as described above, identify a relative feature importance of each feature of the set of features for each model. For example, as shown in FIG. 5, FRS 101 may determine (at 502) the feature importance of each feature of a particular set of features {F₁, F₂, F₃, F₄} by providing these features to multiple models 201-1 through 201-4. For example, as discussed above, for each particular model 201, FRS 101 may evaluate the outputs of modified sets of features (e.g., where one or more of the features {F₁, F₂, F₃, F₄} are omitted) against the outputs of the full set of features {F₁, F₂, F₃, F₄} to identify a relative importance (e.g., a ranking) of each feature.

For example, in the example of FIG. 5, FRS 101 may determine that for model 201-1, feature F₃ is the most important feature (e.g., the removal of feature F₃ had the greatest impact on the output of model 201-1), feature F₁ is the second-most important feature, feature F₂ is the third-most important feature, and that feature F₄ is the fourth-most important feature. On the other hand, for model 201-2, FRS 101 may determine that feature F₂ is the most important feature, feature F₁ is the second-most important feature, feature F₄ is the third-most important feature, and that feature F₃ is the fourth-most important feature. FRS 101 may similarly determine the relative rankings of features {F₁, F₂, F₃, F₄} for models 201-3, 201-4, and/or one or more other models.

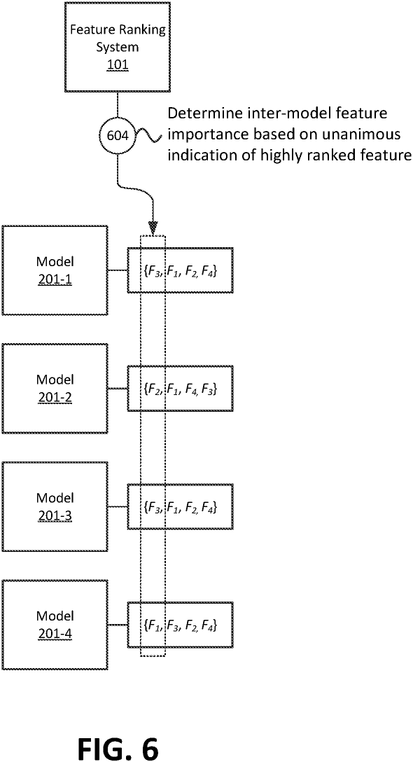

As shown in FIGS. 6-10, FRS 101 may iteratively identify features that have been determined as highly ranking or the highest ranking feature in all models for which features have been ranked (e.g., in a similar fashion as discussed above with respect to FIG. 4). For example, as shown in FIG. 6, FRS 101 may first analyze the highest ranking feature for models 201-1 through 201-4 to determine whether the same feature is the highest ranking feature for models 201-1 through 201-4. In this example, FRS 101 may determine (at 604) that the highest ranking feature for model 201-1 (e.g., when provided the set of features {F₁, F₂, F₃, F₄} as input) is F₃, that the highest ranking feature for model 201-2 is F₂, that the highest ranking feature for model 201-3 is F₃, and that the highest ranking feature for model 201-4 is F₁. Thus, in this iteration, FRS 101 may determine that no feature has been ranked as the highest ranked feature for all of the models 201-1 through 201-4.

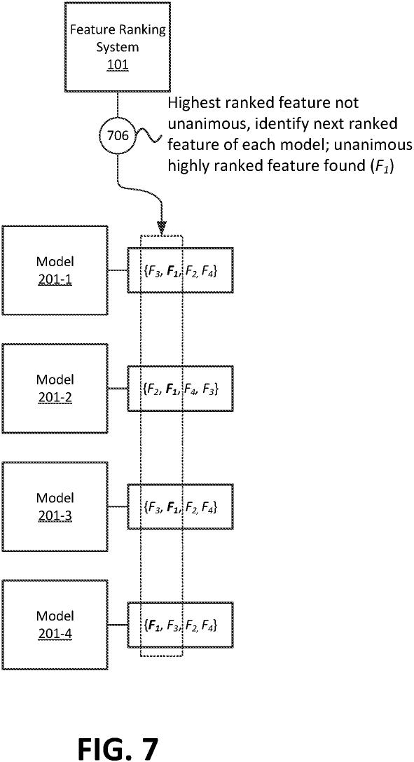

In accordance with some embodiments, since no feature has been ranked as the highest ranked feature for all of the models 201-1 through 201-4, FRS 101 may continue by analyzing the two highest ranked features for all of the models 201-1 through 201-4, to determine which (if any) of the features have been ranked within the top two most impactful features for all of the models 201-1 through 201-4. As shown in FIG. 7, for example, FRS 101 may identify (at 706) that the top two features associated with model 201-1 are features F₃ and F₁, that the top two features associated with model 201-2 are features F₂ and F₁, that the top two features associated with model 201-3 are features F₃ and F₁, and that the top two features associated with model 201-4 are features F₁ and F₃. Thus, feature F₁ may be identified as a feature that is present in the top two ranked features associated with each model 201-1 through 201-4. In other words, feature F₁ may be identified as a unanimous highly ranked feature with respect to models 201-1 through 201-4, when provided the set of features {F₁, F₂, F₃, F₄} as input.

In some embodiments, similar procedures may be performed with different sets of inputs. For example, when provided a different set of inputs, one or more different features (e.g., other than feature F₁) may be identified as a unanimous highly ranked feature with respect to models 201-1 through 201-4.

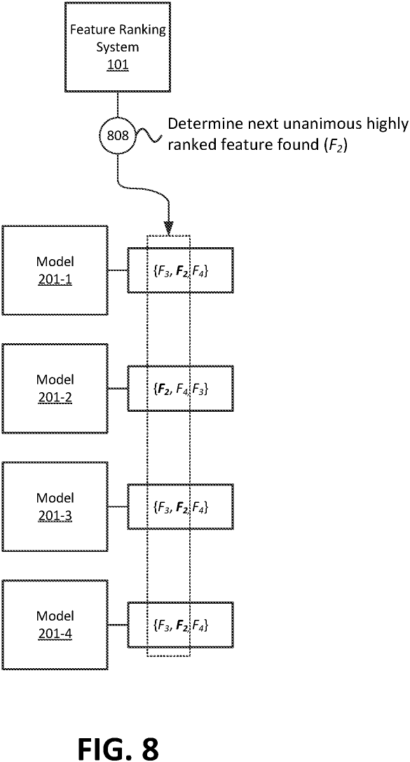

FRS 101 may further identify a next unanimous highly ranked feature. For example, as shown in FIG. 8, FRS 101 may determine (at 808) that feature F₂ is indicated as a feature that is present in the highest ranked features associated with models 201-1 through 201-4 in a similar manner described above. For example, FRS 101 may determine that no feature is unanimously the highest ranked feature associated with models 201-1 through 201-4 (e.g., features F₂ and F₃ are respectively indicated as the highest ranked features for some of models 201-1 through 201-4), and may determine on a subsequent iteration that feature F₂ is indicated in the top two highest ranking features associated with models 201-1 through 201-4. For example, such determination may include omitting feature F₁ from the analysis, as feature F₁ was previously identified as a unanimous highly ranked feature.

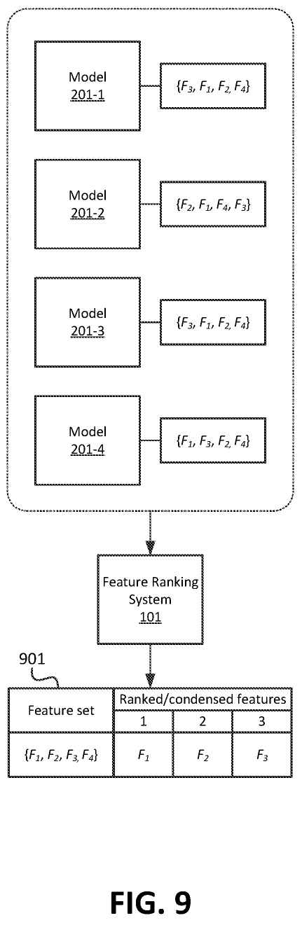

In some embodiments, FRS 101 may continue in a similar manner to evaluate the remaining features of the set of features {F₁, F₂, F₃, F₄} to determine an inter-modal feature importance for the set of features. As shown in FIG. 9, FRS 101 may generate or maintain data structure 901 based on the determination of the inter-model feature importance of the set of features {F₁, F₂, F₃, F₄} in a manner similar to that described above. As shown, for example, data structure may indicate that for a given feature set {F₁, F₂, F₃, F₄}, feature F₁ is the most important (e.g., highest ranked, most impactful, etc.), feature F₂ is the second-most important, and feature F₃ is the third-most important.

In some embodiments, the indicated ranking may be “condensed” with respect to the initial set of features. In this example, while the initial set of features includes feature F₄, the ranked/condensed set of features may omit feature F₄. For example, in some embodiments, the ranked/condensed set may include only a pre-determined quantity of highest ranked features. Additionally, or alternatively, the ranked/condensed set may include only features that are associated with at least a threshold measure of importance. In some embodiments, as noted above with respect to FIG. 4, the measure of importance of a given feature may be based on the difference between outputs of a given model 201 with and without that feature.

While FIG. 9 shows a particular instance of data structure 901, FRS 101 may generate or maintain other instances of data structure 901 for other sets of features. In this manner, FRS 101 may identify relative importance of features in any given set of features. For example, in a first set of features, a particular feature may be relatively highly ranked or the highest ranked feature. In a second set of features, the same particular feature may be relatively lowly ranked or the lowest ranked feature.

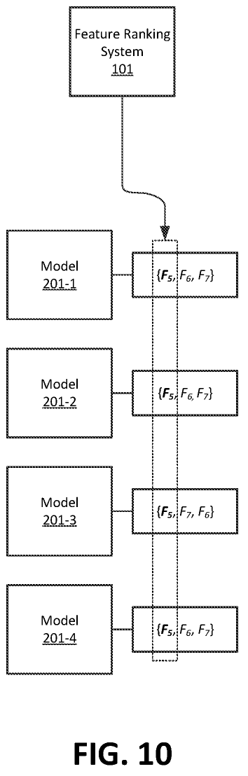

FIG. 10 illustrates another scenario in which a unanimous highly ranked feature may be identified. In this example, feature F₅ may be identified as a unanimous highly ranked feature for models 201-1 through 201-4, as feature F₅ is the highest ranked feature for each model.

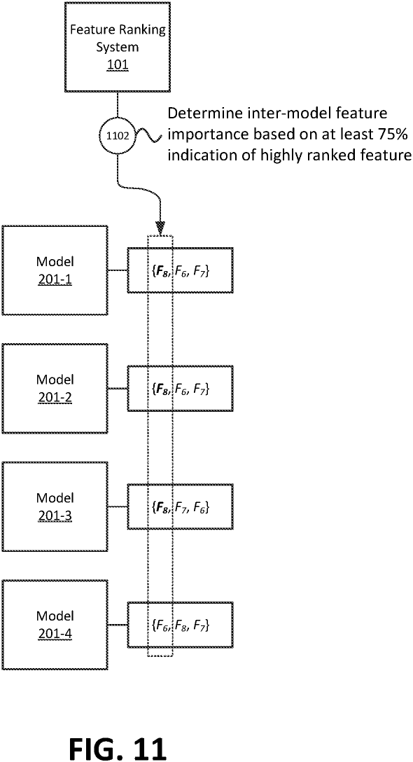

In some embodiments, FRS 101 may determine relative inter-model feature importance without requiring that given features are indicated as a highly (or highest) ranked feature in all models of a set of models. For example, as shown in FIG. 11, FRS 101 may determine (at 1102) that F₈ is the highest ranking feature in at least 75% of models 201-1 through 201-4, and may accordingly determine that F₈ is the highest ranking feature of the set of features {F₆, F₇, F₈}. In some embodiments, a different threshold than 75% may be used, such as 50%, 80%, and/or some other threshold.

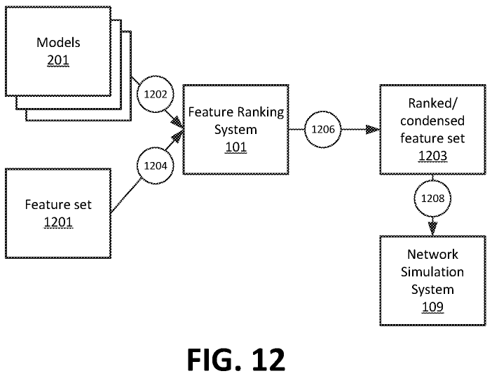

As shown in FIG. 12, in accordance with some embodiments described above, FRS 101 may receive (at 1202) a set of models 201 and may receive (at 1204) a set of features 1201. FRS 101 may generate (at 1206) a ranked/condensed feature set 1203 based on evaluating the features of the set of features 1201 using models 201 (e.g., in a manner similar to that described above). The ranked/condensed set of features 1203 may be provided (at 1208) to NSS 109, which may perform one or more suitable operations, such as network simulations, training machine learning models, and/or other suitable operations, based on the ranked/condensed set of features 1203. In some embodiments, NSS 109 may select particular features from the ranked/condensed set of features 1203, such as a pre-determined quantity of highest ranked features (e.g., the top three features, the top ten features, etc.). In this manner, NSS 109 may be able to perform relatively realistic or reliable simulations (e.g., modeling or simulating wireless network 103 or some other network) without being required to integrate an excessive number of features into one or more models used by NSS 109, thereby reducing time and/or processing resources used to perform the simulations.

In some embodiments, NSS 109 and/or one or more other devices or systems may perform one or more other operations in addition to, or in lieu of, performing one or more simulations based on the ranked/condensed set of features 1203. For example, NSS 109 and/or one or more other devices or systems may generate or modify one or more AI/ML models based on the ranked/condensed set of features 1203. In some embodiments, such models may associate or correlate one or more features with one or more other features. For example, a first feature indicated as relatively highly important (e.g., the highest ranked feature and/or a feature with a ranking that is above a threshold ranking) in the ranked/condensed set of features 1203 may be identified as being correlated to one or more other features (e.g., a second feature of the ranked/condensed set of features 1203 and/or some other feature, attribute, metric, etc.). For example, a characteristic curve between the first feature and the second feature may be determined. In some embodiments, a measure of correlation and/or a some other indicator of relationship between more than two features may be determined.

In this manner, the model may be a predictive model that indicates that an incidence, density, presence, etc. of the first feature likely indicates an incidence, density, presence, etc. of the second feature. In some embodiments, features that are relatively lowly ranked or the lowest ranked features of the ranked/condensed set of features 1203 may not be evaluated in such a manner, thus saving time and/or processing resources in the generation and/or refinement of the models. Further, one or more simulations may be generated and/or performed based on the predictive model and/or characteristic curves that indicates measures of correlations between particular features of the ranked/condensed set of features 1203 and one or more other features.

As noted above, the correlation of features (e.g., characteristic curves or other measures of correlation or relationship) may be used to validate, test, determine a measure of accuracy of, and/or otherwise evaluate one or more models. As one example, a first feature may be associated with a signal quality metric associated with a wireless network, such as Received Signal Strength Indicator (“RSSI”), Signal-to-Interference-and-Noise-Ratio (“SINR”), etc. A second feature may be associated with a measure of dropped calls associated with the wireless network (e.g., 1% of calls dropped, 5% of calls dropped, 98% of calls completed successfully, etc.). The identified correlation of features may include a characteristic curve that reflects that when the signal quality metric is relatively high, the measure of dropped calls is relatively low, and vice versa. Further assume that a network simulation model (e.g., a model generated based on a ranked/condensed set of features in accordance with some embodiments) models, simulates, etc. features including the signal quality metric and the measure of dropped calls. The network simulation model may be validated or otherwise indicated as relatively accurate, predictive, etc. when values for the signal quality metric and the measure of dropped calls are correlated in a manner that matches (or matches within a threshold level of similarity) the characteristic curve. On the other hand, the network simulation model may be invalidated or otherwise indicated as relatively inaccurate, non-predictive, etc. when values for the signal quality metric and the measure of dropped calls are not correlated in a manner that matches (or matches within a threshold level of similarity) the characteristic curve.

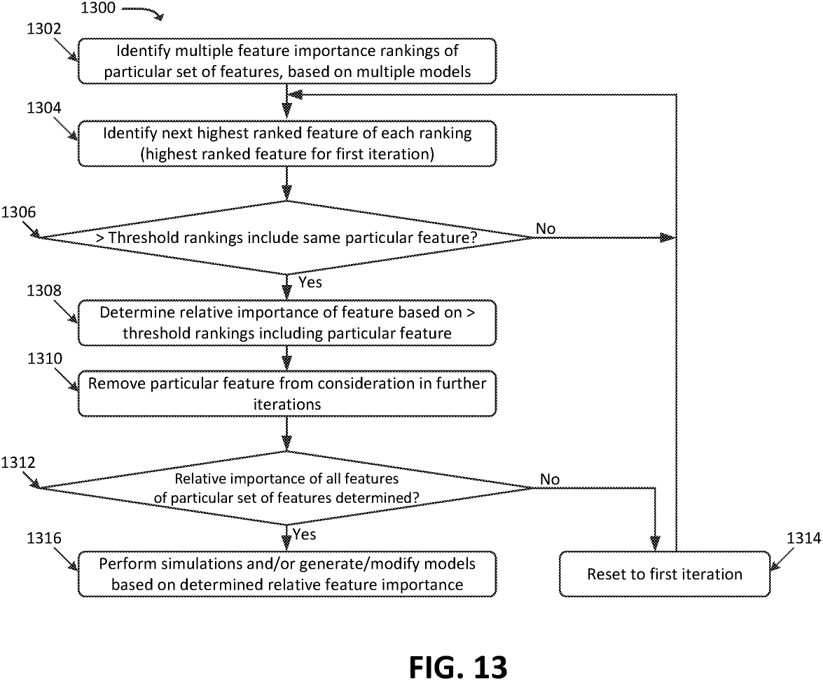

FIG. 13 illustrates an example process 1300 for determining feature importance of a given set of features, in accordance with some embodiments. In some embodiments, some or all of process 1300 may be performed by FRS 101. In some embodiments, one or more other devices may perform some or all of process 1300 in concert with, and/or in lieu of, FRS 101.

As shown, process 1300 may include identifying (at 1302) multiple feature importance rankings of a particular set of features, based on multiple models. For example, as discussed above, FRS 101 may provide the same particular set of features as inputs 203 to multiple models 201. FRS 101 may, for each respective model 201, determine a respective feature importance ranking of the particular set of features. In this manner, the same particular set of features may be ranked differently when provided to different models 201.

As discussed above, determining a particular feature importance ranking for the particular set of features and for a particular model 201 may include identifying an output of the particular model 201 based on providing the particular set of features as input 203 for the particular model 201. Determining the particular feature importance ranking for the particular set of features and the particular model 201 may further include identifying outputs of the particular model 201 based on providing modified versions of the particular set of features (e.g., with one or more features omitted) in order to determine the respective impact of removing a given feature from the inputs 203 provided to the particular model 201. A feature which, when removed from the inputs 203 provided to model 201, had a relatively large impact on the output of model 201 (e.g., as compared to the full set of features) may be identified as a relatively highly ranked feature.

Process 1300 may further include identifying (at 1304) a highest ranked feature of each ranking. For example, as discussed above, FRS 101 may iteratively identify particular positions of the rankings (identified at 1302) to determine features that are indicated as highly important in each ranking, or at in least a threshold quantity or percentage of the rankings. For example, in a first iteration, FRS 101 may identify the highest ranked feature in each ranking (e.g., as indicated in the rankings identified at 1302). In a second iteration, FRS 101 may identify the two highest ranked features in each ranking; in a third iteration, FRS 101 may identify the three highest ranked features in each ranking, and so on.

Process 1300 may additionally include determining (at 1306) whether at least a threshold quantity, percentage, proportion, etc. of the rankings include the same particular feature. For example, in a first iteration, FRS 101 may identify whether the particular feature is the highest ranked feature in at least a threshold percentage (e.g., 100%, 75%, etc.) of the rankings. In a second iteration, FRS 101 may identify whether the particular feature is the highest or second-highest ranked feature in at least the threshold percentage of the rankings.

In situations where the same feature is not present in at least the threshold percentage of rankings (at 1306 – NO), process 1300 may include identifying the next highest ranked feature of each ranking. For example, as discussed above (e.g., with respect to FIG. 6), such a situation may occur when different features are indicated as the highest ranked (e.g., most important) features according to different models 201.

If, on the other hand, the same feature is present in at least the threshold percentage of rankings (at 1308 – YES), then process 1300 may include determining (at 1308) the relative importance of the particular feature based on determining (at 1306) that at least the threshold percentage of rankings include the particular feature within the positions of the rankings being evaluated. That is, in a first iteration, the first or highest position may be evaluated; in a second iteration, the first and second positions may be evaluated; in a third iteration the first, second, and third positions may be evaluated, and so on. The relative feature importance may be determined based on when the particular feature has been identified (at 1306) as being present within the rankings, relative to other features. For example, if a first feature was identified (at 1306) based on a first set of iterations and a second feature was subsequently identified (at 1306) based on a second set of iterations, the relative feature importance of these features may indicate that the first feature is more important than the second feature. In other words, an inter-model feature importance ranking may indicate that the first feature is ranked higher than the second feature.

Process 1300 may also include removing (at 1310) the identified particular feature from consideration in further iterations. That is, once the particular feature as been identified (at 1306), subsequent iterations may be performed to identify the relative importance of other features. If any features remain in the particular set of features and/or if the relative importance of all features of the particular set of features has not been determined (at 1312 – NO), then process 1300 may include resetting (at 1314) to a first iteration, in order to begin evaluating the rankings associated with the multiple models 201 based on the remaining features that have not yet been evaluated.

In some embodiments, when determining (at 1312) whether the relative importance of all features has been determined, FRS 101 may omit features that are below a threshold measure of importance, may limit a quantity of features to include in a ranked/condensed set of features, and/or may limit a quantity of iterations performed (e.g., may not evaluate more than the top 10, top 20, etc. positions in the rankings).

If the relative performance of all of the features has been determined (at 1312 – YES), then process 1300 may include performing (at 1316) one or more simulations and/or generating or modifying models based on the determined relative feature importance of the features. For example, as discussed above, the models and/or simulations may be based on fewer than the full set of features, thereby reducing the complexity and/or processing resource demands associated with such models and/or simulations. Further, in some embodiments, more highly ranked features may be evaluated against other features to identify potential patterns, correlations, characteristic curves, etc.

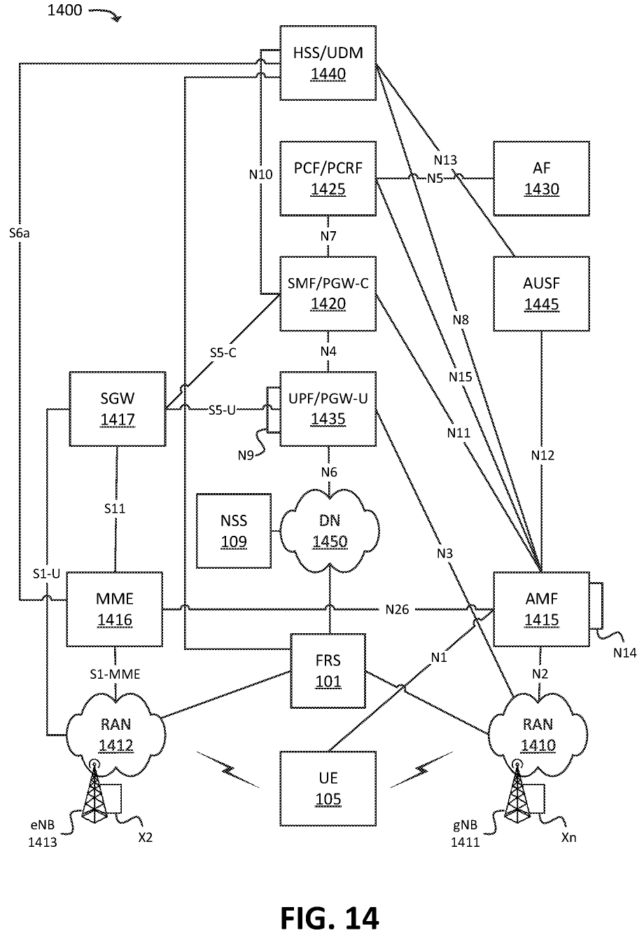

FIG. 14 illustrates an example environment 1400, in which one or more embodiments may be implemented. In some embodiments, environment 1400 may correspond to a Fifth Generation (“5G”) network, and/or may include elements of a 5G network. In some embodiments, environment 1400 may correspond to a 5G Non-Standalone (“NSA”) architecture, in which a 5G radio access technology (“RAT”) may be used in conjunction with one or more other RATs (e.g., a Long-Term Evolution (“LTE”) RAT), and/or in which elements of a 5G core network may be implemented by, may be communicatively coupled with, and/or may include elements of another type of core network (e.g., an evolved packet core (“EPC”)). As shown, environment 1400 may include UE 105, RAN 1410 (which may include one or more Next Generation Node Bs (“gNBs”) 1411), RAN 1412 (which may include one or more evolved Node Bs (“eNBs”) 1413), and various network functions such as Access and Mobility Management Function (“AMF”) 1415, Mobility Management Entity (“MME”) 1416, Serving Gateway (“SGW”) 1417, Session Management Function (“SMF”)/Packet Data Network (“PDN”) Gateway (“PGW”)-Control plane function (“PGW-C”) 1420, Policy Control Function (“PCF”)/Policy Charging and Rules Function (“PCRF”) 1425, Application Function (“AF”) 1430, User Plane Function (“UPF”)/PGW-User plane function (“PGW-U”) 1435, Home Subscriber Server (“HSS”)/Unified Data Management (“UDM”) 1440, and Authentication Server Function (“AUSF”) 1445. Environment 1400 may also include one or more networks, such as Data Network (“DN”) 1450. Environment 1400 may include one or more additional devices or systems communicatively coupled to one or more networks (e.g., DN 1450), such as FRS 101, NSS 109, and/or one or more other devices or systems.

The example shown in FIG. 14 illustrates one instance of each network component or function (e.g., one instance of SMF/PGW-C 1420, PCF/PCRF 1425, UPF/PGW-U 1435, HSS/UDM 1440, and/or AUSF 1445). In practice, environment 1400 may include multiple instances of such components or functions. For example, in some embodiments, environment 1400 may include multiple “slices” of a core network, where each slice includes a discrete set of network functions (e.g., one slice may include a first instance of SMF/PGW-C 1420, PCF/PCRF 1425, UPF/PGW-U 1435, HSS/UDM 1440, and/or AUSF 1445, while another slice may include a second instance of SMF/PGW-C 1420, PCF/PCRF 1425, UPF/PGW-U 1435, HSS/UDM 1440, and/or AUSF 1445). The different slices may provide differentiated levels of service, such as service in accordance with different Quality of Service (“QoS”) parameters.

The quantity of devices and/or networks, illustrated in FIG. 14, is provided for explanatory purposes only. In practice, environment 1400 may include additional devices and/or networks, fewer devices and/or networks, different devices and/or networks, or differently arranged devices and/or networks than illustrated in FIG. 14. For example, while not shown, environment 1400 may include devices that facilitate or enable communication between various components shown in environment 1400, such as routers, modems, gateways, switches, hubs, etc. Alternatively, or additionally, one or more of the devices of environment 1400 may perform one or more network functions described as being performed by another one or more of the devices of environment 1400. Devices of environment 1400 may interconnect with each other and/or other devices via wired connections, wireless connections, or a combination of wired and wireless connections. In some implementations, one or more devices of environment 1400 may be physically integrated in, and/or may be physically attached to, one or more other devices of environment 1400.

UE 105 may include a computation and communication device, such as a wireless mobile communication device that is capable of communicating with RAN 1410, RAN 1412, and/or DN 1450. UE 105 may be, or may include, a radiotelephone, a personal communications system (“PCS”) terminal (e.g., a device that combines a cellular radiotelephone with data processing and data communications capabilities), a personal digital assistant (“PDA”) (e.g., a device that may include a radiotelephone, a pager, Internet/intranet access, etc.), a smart phone, a laptop computer, a tablet computer, a camera, a personal gaming system, an IoT device (e.g., a sensor, a smart home appliance, or the like), a wearable device, an Internet of Things (“IoT”) device, a Machine-to-Machine (“M2M”) device, or another type of mobile computation and communication device. UE 105 may send traffic to and/or receive traffic (e.g., user plane traffic) from DN 1450 via RAN 1410, RAN 1412, and/or UPF/PGW-U 1435.

RAN 1410 may be, or may include, a 5G RAN that includes one or more base stations (e.g., one or more gNBs 1411), via which UE 105 may communicate with one or more other elements of environment 1400. UE 105 may communicate with RAN 1410 via an air interface (e.g., as provided by gNB 1411). For instance, RAN 1410 may receive traffic (e.g., voice call traffic, data traffic, messaging traffic, signaling traffic, etc.) from UE 105 via the air interface, and may communicate the traffic to UPF/PGW-U 1435, and/or one or more other devices or networks. Similarly, RAN 1410 may receive traffic intended for UE 105 (e.g., from UPF/PGW-U 1435, AMF 1415, and/or one or more other devices or networks) and may communicate the traffic to UE 105 via the air interface.

RAN 1412 may be, or may include, a LTE RAN that includes one or more base stations (e.g., one or more eNBs 1413), via which UE 105 may communicate with one or more other elements of environment 1400. UE 105 may communicate with RAN 1412 via an air interface (e.g., as provided by eNB 1413). For instance, RAN 1410 may receive traffic (e.g., voice call traffic, data traffic, messaging traffic, signaling traffic, etc.) from UE 105 via the air interface, and may communicate the traffic to UPF/PGW-U 1435, and/or one or more other devices or networks. Similarly, RAN 1410 may receive traffic intended for UE 105 (e.g., from UPF/PGW-U 1435, SGW 1417, and/or one or more other devices or networks) and may communicate the traffic to UE 105 via the air interface.

AMF 1415 may include one or more devices, systems, Virtualized Network Functions (“VNFs”), etc., that perform operations to register UE 105 with the 5G network, to establish bearer channels associated with a session with UE 105, to hand off UE 105 from the 5G network to another network, to hand off UE 105 from the other network to the 5G network, manage mobility of UE 105 between RANs 1410 and/or gNBs 1411, and/or to perform other operations. In some embodiments, the 5G network may include multiple AMFs 1415, which communicate with each other via the N14 interface (denoted in FIG. 14 by the line marked “N14” originating and terminating at AMF 1415).

MME 1416 may include one or more devices, systems, VNFs, etc., that perform operations to register UE 105 with the EPC, to establish bearer channels associated with a session with UE 105, to hand off UE 105 from the EPC to another network, to hand off UE 105 from another network to the EPC, manage mobility of UE 105 between RANs 1412 and/or eNBs 1413, and/or to perform other operations.

SGW 1417 may include one or more devices, systems, VNFs, etc., that aggregate traffic received from one or more eNBs 1413 and send the aggregated traffic to an external network or device via UPF/PGW-U 1435. Additionally, SGW 1417 may aggregate traffic received from one or more UPF/PGW-Us 1435 and may send the aggregated traffic to one or more eNBs 1413. SGW 1417 may operate as an anchor for the user plane during inter-eNB handovers and as an anchor for mobility between different telecommunication networks or RANs (e.g., RANs 1410 and 1412).

SMF/PGW-C 1420 may include one or more devices, systems, VNFs, etc., that gather, process, store, and/or provide information in a manner described herein. SMF/PGW-C 1420 may, for example, facilitate the establishment of communication sessions on behalf of UE 105. In some embodiments, the establishment of communications sessions may be performed in accordance with one or more policies provided by PCF/PCRF 1425.

PCF/PCRF 1425 may include one or more devices, systems, VNFs, etc., that aggregate information to and from the 5G network and/or other sources. PCF/PCRF 1425 may receive information regarding policies and/or subscriptions from one or more sources, such as subscriber databases and/or from one or more users (such as, for example, an administrator associated with PCF/PCRF 1425).

AF 1430 may include one or more devices, systems, VNFs, etc., that receive, store, and/or provide information that may be used in determining parameters (e.g., quality of service parameters, charging parameters, or the like) for certain applications.

UPF/PGW-U 1435 may include one or more devices, systems, VNFs, etc., that receive, store, and/or provide data (e.g., user plane data). For example, UPF/PGW-U 1435 may receive user plane data (e.g., voice call traffic, data traffic, etc.), destined for UE 105, from DN 1450, and may forward the user plane data toward UE 105 (e.g., via RAN 1410, SMF/PGW-C 1420, and/or one or more other devices). In some embodiments, multiple UPFs 1435 may be deployed (e.g., in different geographical locations), and the delivery of content to UE 105 may be coordinated via the N9 interface (e.g., as denoted in FIG. 14 by the line marked “N9” originating and terminating at UPF/PGW-U 1435). Similarly, UPF/PGW-U 1435 may receive traffic from UE 105 (e.g., via RAN 1410, SMF/PGW-C 1420, and/or one or more other devices), and may forward the traffic toward DN 1450. In some embodiments, UPF/PGW-U 1435 may communicate (e.g., via the N4 interface) with SMF/PGW-C 1420, regarding user plane data processed by UPF/PGW-U 1435.

HSS/UDM 1440 and AUSF 1445 may include one or more devices, systems, VNFs, etc., that manage, update, and/or store, in one or more memory devices associated with AUSF 1445 and/or HSS/UDM 1440, profile information associated with a subscriber. AUSF 1445 and/or HSS/UDM 1440 may perform authentication, authorization, and/or accounting operations associated with the subscriber and/or a communication session with UE 105.

DN 1450 may include one or more wired and/or wireless networks. For example, DN 1450 may include an Internet Protocol (“IP”)-based PDN, a wide area network (“WAN”) such as the Internet, a private enterprise network, and/or one or more other networks. UE 105 may communicate, through DN 1450, with data servers, other UEs 105, and/or to other servers or applications that are coupled to DN 1450. DN 1450 may be connected to one or more other networks, such as a public switched telephone network (“PSTN”), a public land mobile network (“PLMN”), and/or another network. DN 1450 may be connected to one or more devices, such as content providers, applications, web servers, and/or other devices, with which UE 105 may communicate.

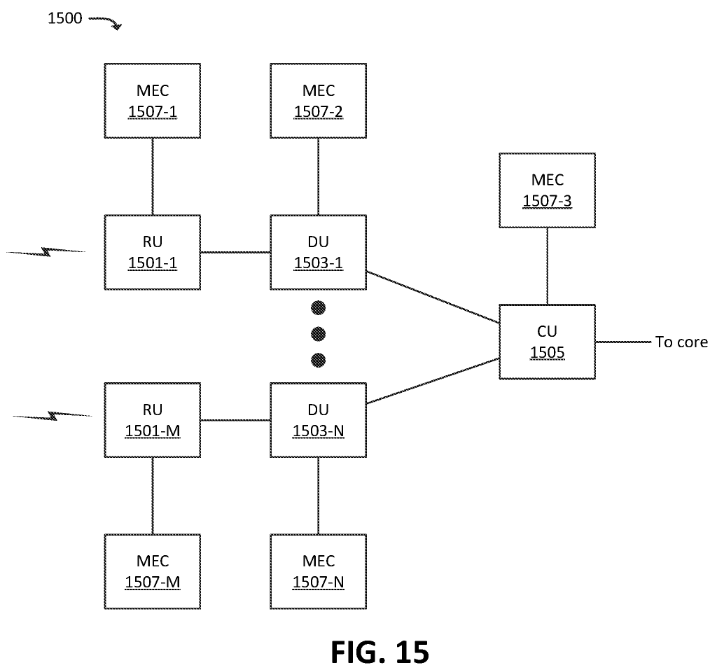

FIG. 15 illustrates an example Distributed Unit (“DU”) network 1500, which may be included in and/or implemented by one or more RANs (e.g., RAN 1410, RAN 1412, or some other RAN). In some embodiments, a particular RAN may include one DU network 1500. In some embodiments, a particular RAN may include multiple DU networks 1500. In some embodiments, DU network 1500 may correspond to a particular gNB 1411 of a 5G RAN (e.g., RAN 1410). In some embodiments, DU network 1500 may correspond to multiple gNBs 1411. In some embodiments, DU network 1500 may correspond to one or more other types of base stations of one or more other types of RANs. As shown, DU network 1500 may include Central Unit (“CU”) 1505, one or more Distributed Units (“DUs”) 1503-1 through 1503-N (referred to individually as “DU 1503,” or collectively as “DUs 1503”), and one or more Radio Units (“RUs”) 1501-1 through 1501-M (referred to individually as “RU 1501,” or collectively as “RUs 1501”).

CU 1505 may communicate with a core of a wireless network (e.g., may communicate with one or more of the devices or systems described above with respect to FIG. 14, such as AMF 1415 and/or UPF/PGW-U 1435). In the uplink direction (e.g., for traffic from UEs 105 to a core network), CU 1505 may aggregate traffic from DUs 1503, and forward the aggregated traffic to the core network. In some embodiments, CU 1505 may receive traffic according to a given protocol (e.g., Radio Link Control (“RLC”)) from DUs 1503, and may perform higher-layer processing (e.g., may aggregate/process RLC packets and generate Packet Data Convergence Protocol (“PDCP”) packets based on the RLC packets) on the traffic received from DUs 1503.

In accordance with some embodiments, CU 1505 may receive downlink traffic (e.g., traffic from the core network) for a particular UE 105, and may determine which DU(s) 1503 should receive the downlink traffic. DU 1503 may include one or more devices that transmit traffic between a core network (e.g., via CU 1505) and UE 105 (e.g., via a respective RU 1501). DU 1503 may, for example, receive traffic from RU 1501 at a first layer (e.g., physical (“PHY”) layer traffic, or lower PHY layer traffic), and may process/aggregate the traffic to a second layer (e.g., upper PHY and/or RLC). DU 1503 may receive traffic from CU 1505 at the second layer, may process the traffic to the first layer, and provide the processed traffic to a respective RU 1501 for transmission to UE 105.

RU 1501 may include hardware circuitry (e.g., one or more RF transceivers, antennas, radios, and/or other suitable hardware) to communicate wirelessly (e.g., via an RF interface) with one or more UEs 105, one or more other DUs 1503 (e.g., via RUs 1501 associated with DUs 1503), and/or any other suitable type of device. In the uplink direction, RU 1501 may receive traffic from UE 105 and/or another DU 1503 via the RF interface and may provide the traffic to DU 1503. In the downlink direction, RU 1501 may receive traffic from DU 1503, and may provide the traffic to UE 105 and/or another DU 1503.

RUs 1501 may, in some embodiments, be communicatively coupled to one or more Multi-Access/Mobile Edge Computing (“MEC”) devices, referred to sometimes herein simply as “MECs” 1507. For example, RU 1501-1 may be communicatively coupled to MEC 1507-1, RU 1501-M may be communicatively coupled to MEC 1507-M, DU 1503-1 may be communicatively coupled to MEC 1507-2, DU 1503-N may be communicatively coupled to MEC 1507-N, CU 1505 may be communicatively coupled to MEC 1507-3, and so on. MECs 1507 may include hardware resources (e.g., configurable or provisionable hardware resources) that may be configured to provide services and/or otherwise process traffic to and/or from UE 105, via a respective RU 1501.

For example, RU 1501-1 may route some traffic, from UE 105, to MEC 1507-1 instead of to a core network (e.g., via DU 1503 and CU 1505). MEC 1507-1 may process the traffic, perform one or more computations based on the received traffic, and may provide traffic to UE 105 via RU 1501-1. In this manner, ultra-low latency services may be provided to UE 105, as traffic does not need to traverse DU 1503, CU 1505, and an intervening backhaul network between DU network 1500 and the core network. In some embodiments, MEC 1507 may include, and/or may implement, some or all of the functionality described above with respect to FRS 101.

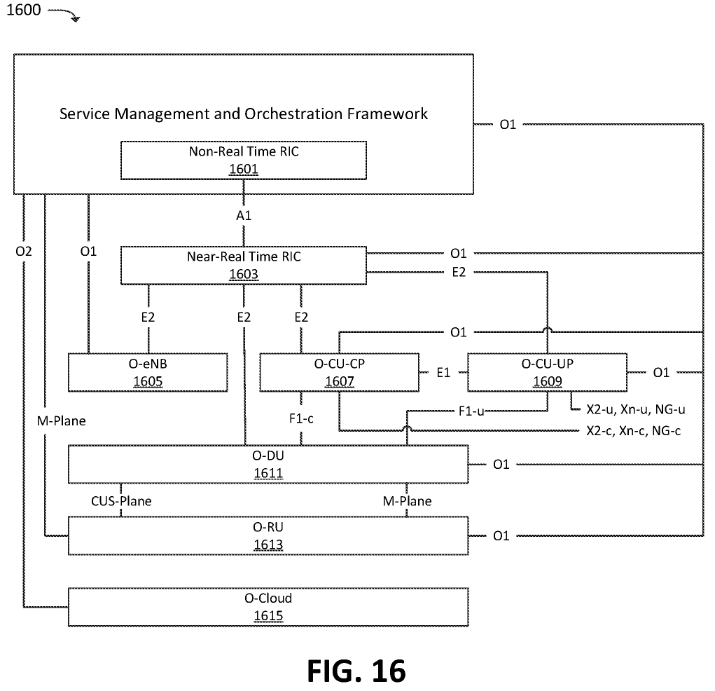

FIG. 16 illustrates an example O-RAN environment 1600, which may correspond to RAN 1410, RAN 1412, and/or DU network 1500. For example, RAN 1410, RAN 1412, and/or DU network 1500 may include one or more instances of O-RAN environment 1600, and/or one or more instances of O-RAN environment 1600 may implement RAN 1410, RAN 1412, DU network 1500, and/or some portion thereof. As shown, O-RAN environment 1600 may include Non-Real Time Radio Intelligent Controller (“RIC”) 1601, Near-Real Time RIC 1603, O-eNB 1605, O-CU-Control Plane (“O-CU-CP”) 1607, O-CU-User Plane (“O-CU-UP”) 1609, O-DU 1611, O-RU 1613, and O-Cloud 1615. In some embodiments, O-RAN environment 1600 may include additional, fewer, different, and/or differently arranged components. In some embodiments, features evaluated with respect to one or more models 201 (e.g., as described above) may include configuration parameters, attributes, and/or other features of one or more elements of environment 1600.

In some embodiments, some or all of the elements of O-RAN environment 1600 may be implemented by one or more configurable or provisionable resources, such as virtual machines, cloud computing systems, physical servers, and/or other types of configurable or provisionable resources. In some embodiments, some or all of O-RAN environment 1600 may be implemented by, and/or communicatively coupled to, one or more MECs 1507.

Non-Real Time RIC 1601 and Near-Real Time RIC 1603 may receive performance information (and/or other types of information) from one or more sources, and may configure other elements of O-RAN environment 1600 based on such performance or other information. For example, Near-Real Time RIC 1603 may receive performance information, via one or more E2 interfaces, from O-eNB 1605, O-CU-CP 1607, and/or O-CU-UP 1609, and may modify parameters associated with O-eNB 1605, O-CU-CP 1607, and/or O-CU-UP 1609 based on such performance information. Similarly, Non-Real Time RIC 1601 may receive performance information associated with O-eNB 1605, O-CU-CP 1607, O-CU-UP 1609, and/or one or more other elements of O-RAN environment 1600 and may utilize machine learning and/or other higher level computing or processing to determine modifications to the configuration of O-eNB 1605, O-CU-CP 1607, O-CU-UP 1609, and/or other elements of O-RAN environment 1600. In some embodiments, Non-Real Time RIC 1601 may generate machine learning models based on performance information associated with O-RAN environment 1600 or other sources, and may provide such models to Near-Real Time RIC 1603 for implementation.

O-eNB 1605 may perform functions similar to those described above with respect to eNB 1413. For example, O-eNB 1605 may facilitate wireless communications between UE 105 and a core network. O-CU-CP 1607 may perform control plane signaling to coordinate the aggregation and/or distribution of traffic via one or more DUs 1503, which may include and/or be implemented by one or more O-DUs 1611, and O-CU-UP 1609 may perform the aggregation and/or distribution of traffic via such DUs 1503 (e.g., O-DUs 1611). O-DU 1611 may be communicatively coupled to one or more RUs 1501, which may include and/or may be implemented by one or more O-RUs 1613. In some embodiments, O-Cloud 1615 may include or be implemented by one or more MECs 1507, which may provide services, and may be communicatively coupled, to O-CU-CP 1607, O-CU-UP 1609, O-DU 1611, and/or O-RU 1613 (e.g., via an O1 and/or O2 interface).

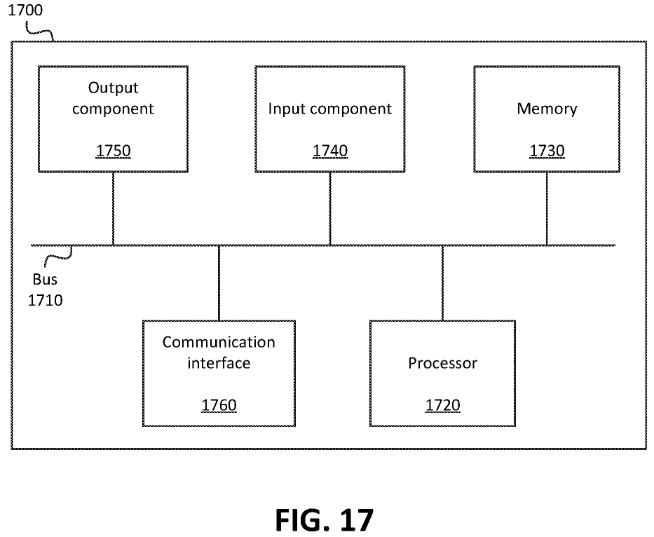

FIG. 17 illustrates example components of device 1700. One or more of the devices described above may include one or more devices 1700. Device 1700 may include bus 1710, processor 1720, memory 1730, input component 1740, output component 1750, and communication interface 1760. In another implementation, device 1700 may include additional, fewer, different, or differently arranged components.

Bus 1710 may include one or more communication paths that permit communication among the components of device 1700. Processor 1720 may include a processor, microprocessor, or processing logic that may interpret and execute instructions. In some embodiments, processor 1720 may be or may include one or more hardware processors. Memory 1730 may include any type of dynamic storage device that may store information and instructions for execution by processor 1720, and/or any type of non-volatile storage device that may store information for use by processor 1720.

Input component 1740 may include a mechanism that permits an operator to input information to device 1700 and/or other receives or detects input from a source external to 1740, such as a touchpad, a touchscreen, a keyboard, a keypad, a button, a switch, a microphone or other audio input component, etc. In some embodiments, input component 1740 may include, or may be communicatively coupled to, one or more sensors, such as a motion sensor (e.g., which may be or may include a gyroscope, accelerometer, or the like), a location sensor (e.g., a Global Positioning System (“GPS”)-based location sensor or some other suitable type of location sensor or location determination component), a thermometer, a barometer, and/or some other type of sensor. Output component 1750 may include a mechanism that outputs information to the operator, such as a display, a speaker, one or more light emitting diodes (“LEDs”), etc.

Communication interface 1760 may include any transceiver-like mechanism that enables device 1700 to communicate with other devices and/or systems. For example, communication interface 1760 may include an Ethernet interface, an optical interface, a coaxial interface, or the like. Communication interface 1760 may include a wireless communication device, such as an infrared (“IR”) receiver, a Bluetooth® radio, or the like. The wireless communication device may be coupled to an external device, such as a remote control, a wireless keyboard, a mobile telephone, etc. In some embodiments, device 1700 may include more than one communication interface 1760. For instance, device 1700 may include an optical interface and an Ethernet interface.

Device 1700 may perform certain operations relating to one or more processes described above. Device 1700 may perform these operations in response to processor 1720 executing software instructions stored in a computer-readable medium, such as memory 1730. A computer-readable medium may be defined as a non-transitory memory device. A memory device may include space within a single physical memory device or spread across multiple physical memory devices. The software instructions may be read into memory 1730 from another computer-readable medium or from another device. The software instructions stored in memory 1730 may cause processor 1720 to perform processes described herein. Alternatively, hardwired circuitry may be used in place of or in combination with software instructions to implement processes described herein. Thus, implementations described herein are not limited to any specific combination of hardware circuitry and software.

The foregoing description of implementations provides illustration and description, but is not intended to be exhaustive or to limit the possible implementations to the precise form disclosed. Modifications and variations are possible in light of the above disclosure or may be acquired from practice of the implementations.

For example, while series of blocks and/or signals have been described above (e.g., with regard to FIGS. 1-13), the order of the blocks and/or signals may be modified in other implementations. Further, non-dependent blocks and/or signals may be performed in parallel. Additionally, while the figures have been described in the context of particular devices performing particular acts, in practice, one or more other devices may perform some or all of these acts in lieu of, or in addition to, the above-mentioned devices.

The actual software code or specialized control hardware used to implement an embodiment is not limiting of the embodiment. Thus, the operation and behavior of the embodiment has been described without reference to the specific software code, it being understood that software and control hardware may be designed based on the description herein.

In the preceding specification, various example embodiments have been described with reference to the accompanying drawings. It will, however, be evident that various modifications and changes may be made thereto, and additional embodiments may be implemented, without departing from the broader scope of the invention as set forth in the claims that follow. The specification and drawings are accordingly to be regarded in an illustrative rather than restrictive sense.

Even though particular combinations of features are recited in the claims and/or disclosed in the specification, these combinations are not intended to limit the disclosure of the possible implementations. In fact, many of these features may be combined in ways not specifically recited in the claims and/or disclosed in the specification. Although each dependent claim listed below may directly depend on only one other claim, the disclosure of the possible implementations includes each dependent claim in combination with every other claim in the claim set.

Further, while certain connections or devices are shown, in practice, additional, fewer, or different, connections or devices may be used. Furthermore, while various devices and networks are shown separately, in practice, the functionality of multiple devices may be performed by a single device, or the functionality of one device may be performed by multiple devices. Further, multiple ones of the illustrated networks may be included in a single network, or a particular network may include multiple networks. Further, while some devices are shown as communicating with a network, some such devices may be incorporated, in whole or in part, as a part of the network.

To the extent the aforementioned implementations collect, store, or employ personal information of individuals, groups or other entities, it should be understood that such information shall be used in accordance with all applicable laws concerning protection of personal information. Additionally, the collection, storage, and use of such information can be subject to consent of the individual to such activity, for example, through well known “opt-in” or “opt-out” processes as can be appropriate for the situation and type of information. Storage and use of personal information can be in an appropriately secure manner reflective of the type of information, for example, through various access control, encryption and anonymization techniques for particularly sensitive information.

No element, act, or instruction used in the present application should be construed as critical or essential unless explicitly described as such. An instance of the use of the term “and,” as used herein, does not necessarily preclude the interpretation that the phrase “and/or” was intended in that instance. Similarly, an instance of the use of the term “or,” as used herein, does not necessarily preclude the interpretation that the phrase “and/or” was intended in that instance. Also, as used herein, the article “a” is intended to include one or more items, and may be used interchangeably with the phrase “one or more.” Where only one item is intended, the terms “one,” “single,” “only,” or similar language is used. Further, the phrase “based on” is intended to mean “based, at least in part, on” unless explicitly stated otherwise.

What is claimed is:

1. A device, comprising:
one or more processors configured to:
identify a plurality of rankings of a particular set of features, wherein each ranking, of the plurality of rankings, is associated with a particular model of a plurality of models;
determine, based on the plurality of rankings of the particular set of features, relative measures of feature importance associated with one or more features, of the particular set of features, with respect to one or more other features of the particular set of features; and
perform one or more simulations based on the relative measures of feature importance associated with the one or more features, wherein performing the one or more simulations includes using at least one of the one or more features as configuration parameters for the one or more simulations.

2. The device of claim 1, wherein identifying the plurality of rankings includes:
identifying a first ranking of the particular set of features, the first ranking being based on a first model of the plurality of models; and
identifying a second ranking of the particular set of features, the second ranking being based on a second model of the plurality of models.

3. The device of claim 2, wherein the particular set of features includes at least first and second features,
wherein the first ranking includes the first feature as a highest ranked feature and further includes the second feature as a feature that is ranked lower than the first feature, and
and wherein the second ranking includes the second feature as a highest ranked feature and further includes the first feature as a feature that is ranked lower than the second feature.

4. The device of claim 1, wherein the one or more processors are further configured to:
provide the particular set of features as input to a first model of the plurality of models; and
determine a first ranking, of the plurality of rankings, based on an output of the first model that is based on the particular set of features provided as input to the first model.

5. The device of claim 4, wherein determining the first ranking includes:
determining a first output of the first model based on providing the particular set of features as input to the first model;
determining a second output of the first model based on providing a subset of the particular set of features as input to the first model, the subset omitting a first feature of the particular set of features;
determining a measure of similarity between the first output and the second output, wherein a position of the first feature in the first ranking is based on the determined measure of similarity.

6. The device of claim 1, wherein the one or more simulations include one or more simulations of a wireless network, and wherein the configuration parameters include configuration parameters of one or more network elements of the wireless network.

7. The device of claim 1, wherein determining the relative measures of feature importance associated with the one or more features includes:
identifying a particular feature, of the particular set of features, that is present within at least a first threshold quantity of highest ranked positions in at least a second threshold quantity of rankings of the plurality of rankings.

8. A non-transitory computer-readable medium, storing a plurality of processor-executable instructions to:
identify a plurality of rankings of a particular set of features, wherein each ranking, of the plurality of rankings, is associated with a particular model of a plurality of models;
determine, based on the plurality of rankings of the particular set of features, relative measures of feature importance associated with one or more features, of the particular set of features, with respect to one or more other features of the particular set of features; and
perform one or more simulations based on the relative measures of feature importance associated with the one or more features, wherein performing the one or more simulations includes using at least one of the one or more features as configuration parameters for the one or more simulations.

9. The non-transitory computer-readable medium of claim 8, wherein identifying the plurality of rankings includes:
identifying a first ranking of the particular set of features, the first ranking being based on a first model of the plurality of models; and
identifying a second ranking of the particular set of features, the second ranking being based on a second model of the plurality of models.

10. The non-transitory computer-readable medium of claim 9, wherein the particular set of features includes at least first and second features,
wherein the first ranking includes the first feature as a highest ranked feature and further includes the second feature as a feature that is ranked lower than the first feature, and
and wherein the second ranking includes the second feature as a highest ranked feature and further includes the first feature as a feature that is ranked lower than the second feature.

11. The non-transitory computer-readable medium of claim 8, wherein the plurality of processor-executable instructions further include processor-executable instructions to:
provide the particular set of features as input to a first model of the plurality of models; and
determine a first ranking, of the plurality of rankings, based on an output of the first model that is based on the particular set of features provided as input to the first model.

12. The non-transitory computer-readable medium of claim 11, wherein determining the first ranking includes:
determining a first output of the first model based on providing the particular set of features as input to the first model;
determining a second output of the first model based on providing a subset of the particular set of features as input to the first model, the subset omitting a first feature of the particular set of features;
determining a measure of similarity between the first output and the second output, wherein a position of the first feature in the first ranking is based on the determined measure of similarity.

13. The non-transitory computer-readable medium of claim 8, wherein the one or more simulations include one or more simulations of a wireless network, and wherein the configuration parameters include configuration parameters of one or more network elements of the wireless network.

14. The non-transitory computer-readable medium of claim 8, wherein determining the relative measures of feature importance associated with the one or more features includes:
identifying a particular feature, of the particular set of features, that is present within at least a first threshold quantity of highest ranked positions in at least a second threshold quantity of rankings of the plurality of rankings.

15. A method, comprising:
identifying a plurality of rankings of a particular set of features, wherein each ranking, of the plurality of rankings, is associated with a particular model of a plurality of models;
determining, based on the plurality of rankings of the particular set of features, relative measures of feature importance associated with one or more features, of the particular set of features, with respect to one or more other features of the particular set of features; and
performing one or more simulations based on the relative measures of feature importance associated with the one or more features, wherein performing the one or more simulations includes using at least one of the one or more features as configuration parameters for the one or more simulations.

16. The method of claim 15, wherein the particular set of features includes at least first and second features, wherein identifying the plurality of rankings includes:
identifying a first ranking of the particular set of features, the first ranking being based on a first model of the plurality of models, wherein the first ranking includes the first feature as a highest ranked feature and further includes the second feature as a feature that is ranked lower than the first feature; and
identifying a second ranking of the particular set of features, the second ranking being based on a second model of the plurality of models, wherein the second ranking includes the second feature as a highest ranked feature and further includes the first feature as a feature that is ranked lower than the second feature.

17. The method of claim 15, the method further comprising:
providing the particular set of features as input to a first model of the plurality of models; and
determining a first ranking, of the plurality of rankings, based on an output of the first model that is based on the particular set of features provided as input to the first model.

18. The method of claim 17, wherein determining the first ranking includes:
determining a first output of the first model based on providing the particular set of features as input to the first model;
determining a second output of the first model based on providing a subset of the particular set of features as input to the first model, the subset omitting a first feature of the particular set of features;
determining a measure of similarity between the first output and the second output, wherein a position of the first feature in the first ranking is based on the determined measure of similarity.

19. The method of claim 15, wherein the one or more simulations include one or more simulations of a wireless network, and wherein the configuration parameters include configuration parameters of one or more network elements of the wireless network.

20. The method of claim 15, wherein determining the relative measures of feature importance associated with the one or more features includes:
identifying a particular feature, of the particular set of features, that is present within at least a first threshold quantity of highest ranked positions in at least a second threshold quantity of rankings of the plurality of rankings.
